(19) United States
(12) Patent Application Publication
(10) Pub. No.: US 2025/0038103 A1
(43) Pub. Date: Jan. 30, 2025

(54) STRUCTURE OF MIM CAPACITOR AND HEAT SINK

(71) Applicant: UNITED MICROELECTRONICS CORP., Hsin-Chu City (TW)

(72) Inventors: Da-Jun Lin, Kaohsiung City (TW); Bin-Siang Tsai, Changhua County (TW); Fu-Yu Tsai, Tainan City (TW); Chung-Yi Chiu, Tainan City (TW)

(73) Assignee: UNITED MICROELECTRONICS CORP., Hsin-Chu City (TW)

(21) Appl. No.: 18/233,877

(22) Filed: Aug. 14, 2023

(30) Foreign Application Priority Data
Jul. 24, 2023 (CN) 202310908745.7

(51) Int. Cl. H01L 23/522; H01L 23/36; H01L 23/528

(52) U.S. Cl. CPC H01L 23/5223; H01L 23/36; H01L 23/5283; H01L 28/60

(57) ABSTRACT

A structure of an MIM capacitor and a heat sink include a dielectric layer. The dielectric layer includes a capacitor region and a heat dispensing region. A bottom electrode is embedded in the dielectric layer. A first heat conductive layer covers the dielectric layer. A capacitor dielectric layer is disposed on the first heat conductive layer within the capacitor region. A second heat conductive layer covers and contacts the capacitor dielectric layer and the first heat conductive layer. A top electrode is disposed within the capacitor region and the heat dispensing region and covers the second heat conductive layer. A first heat sink is disposed within the heat dispensing region and contacts the top electrode. A second heat sink is disposed within the heat dispensing region and contacts the first heat conductive layer and the second heat conductive layer.

### BACKGROUND OF THE INVENTION

### 1. Field of the Invention

The invention relates to a structure of a metal-insulator-metal (MIM) capacitor and a heat sink, and more particularly to a structure in which a heat conductive layer is disposed on a capacitor dielectric layer to conduct heat to a heat sink and a manufacturing method thereof.

### 2. Description of the Prior Art

The power amplifier is an important component in the radio frequency transmission circuit. Its main function is to amplify the signal and send it out. It is usually designed at the front of the antenna radiator. Currently, power amplifiers are used in a variety of semiconductor components.

With the rapid development of the electronic industry, electronic products have become thinner, and integration has also increased. Therefore, the circuit boards used to carry electronic devices such as resistors, capacitors, and chips are also in need to become thinner. With the increasing popularity of wireless communications and the development of miniaturized communication equipment, power amplifiers will be formed in more intensive way. However, under high-frequency operation in a limited space, a large amount of heat will be generated, which will affect the normal operation of the power amplifier.

### SUMMARY OF THE INVENTION

In view of this, the present invention provides a structure of an MIM capacitor and a heat sink with good heat dispensing ability, therefore overheat of the power amplifier can be effectively avoided.

According to a preferred embodiment of the present invention, a structure of an MIM capacitor and a heat sink includes a dielectric layer, wherein the dielectric layer includes a capacitor region and a heat dispensing region. A bottom electrode is embedded in the dielectric layer. A first heat conductive layer covers the dielectric layer and the heat dispensing region. A capacitor dielectric layer is disposed on the first heat conductive layer within the capacitor region. A second heat conductive layer covers and contacts the capacitor dielectric layer and the first heat conductive layer, wherein the second heat conductive layer is disposed within the capacitor region and the heat dispensing region. A top electrode is disposed within the capacitor region and the heat dispensing region, and covers the second heat conductive layer. A first heat sink is disposed within the heat dispensing region and contacts the top electrode. A second heat sink is disposed within the heat dispensing region and contacts the first heat conductive layer and the second heat conductive layer.

According to another preferred embodiment of the present invention, a fabricating method of a structure of an MIM capacitor and a heat sink includes providing a dielectric layer, wherein the dielectric layer includes a capacitor region and a heat dispensing region. Next, a bottom electrode is formed to be embedded in the dielectric layer. Then, a first heat conductive layer is formed to cover the capacitor region and the heat dispensing region of the dielectric layer. After that, a capacitor dielectric layer is formed to be disposed on the first heat conductive layer within the capacitor region. Subsequently, a second heat conductive layer is formed to cover and contact the capacitor dielectric layer and the first heat conductive layer, wherein the second heat conductive layer is disposed within the capacitor region and the heat dispensing region. Thereafter, a top electrode is formed to be disposed within the capacitor region and the heat dispensing region, wherein the top electrode covers the second heat conductive layer. Next, a first heat sink is formed to be disposed on the heat dispensing region and contacts the top electrode. Finally, a second heat sink is formed to be disposed within the heat dispensing region, contacts the first heat conductive layer and the second heat conductive layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 depict a fabricating method of a structure of an MIM capacitor and a heat sink according to a preferred embodiment of the present invention, wherein:

FIG. 1 depicts a dielectric layer with an active region, a capacitor region and a heat dissipating region;

FIG. 2 is a fabricating stage in continuous of FIG. 1;

FIG. 3 is a fabricating stage in continuous of FIG. 2;

FIG. 4 is a fabricating stage in continuous of FIG. 3;

FIG. 5 is a fabricating stage in continuous of FIG. 4; and

FIG. 6 is a fabricating stage in continuous of FIG. 5.

### DETAILED DESCRIPTION

FIG. 1 to FIG. 6 depict a fabricating method of a structure of an MIM capacitor and a heat sink according to a preferred embodiment of the present invention.

As shown in FIG. 1, a dielectric layer 10a is provided, wherein the dielectric layer 10a includes an active region A, a capacitor region B and a heat dissipating region C. A substrate 12 is disposed below the dielectric layer 10a. The substrate 12 is covered with an interlayer dielectric layer 10b, and the interlayer dielectric layer 10b contacts the dielectric layer 10a. The substrate 12, the interlayer dielectric layer 10b and the dielectric layer 10a are all divided into the active region A, the capacitor region B and the heat dissipating region C. A power amplifier 14 is disposed on the substrate 12 within the active region A. A metal interconnection structure 20b is disposed in the interlayer dielectric layer 10b to electrically connect the power amplifier 14.

Later, a bottom electrode 16 is formed to be embedded in the dielectric layer 10a within the capacitor region B. A metal interconnection structure 20a is formed to be disposed in the dielectric layer 10a within the active region A. The metal interconnect structure 20a contacts the metal interconnect structure 20b.

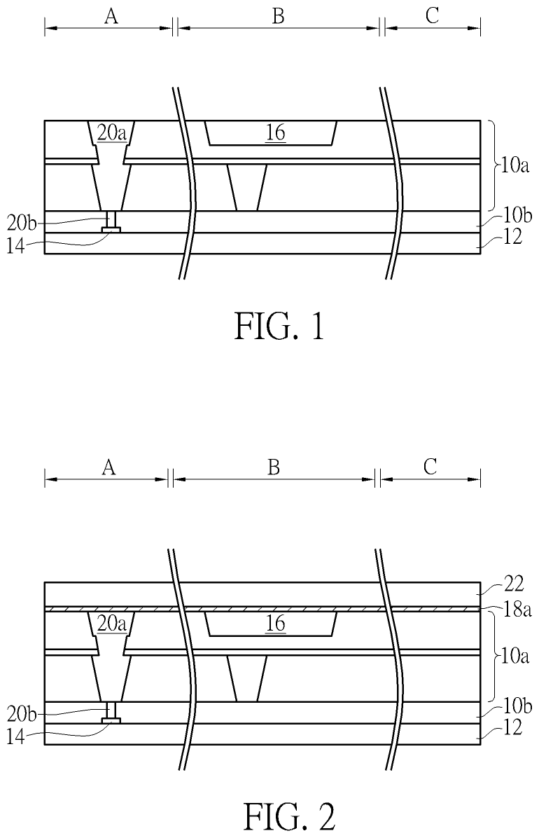

As shown in FIG. 2, a first heat conductive layer 18a is formed to cover the dielectric layer 10a within the active region A, the capacitor region B and the heat dissipating region C. Then, a capacitor dielectric layer 22 is formed to cover the first heat conductive layer 18a. The capacitor dielectric layer 22 is disposed in the active region A, the capacitor region B and the heat dissipating region C. The first heat conductive layer 18a is preferably amorphous aluminum nitride or amorphous boron nitride. The capacitor dielectric layer 22 is preferably with a high dielectric constant. The first heat conductive layer 18a and the capacitor dielectric layer 22 can be formed by a physical vapor deposition, a chemical vapor deposition, an atomic layer deposition or other depositions.

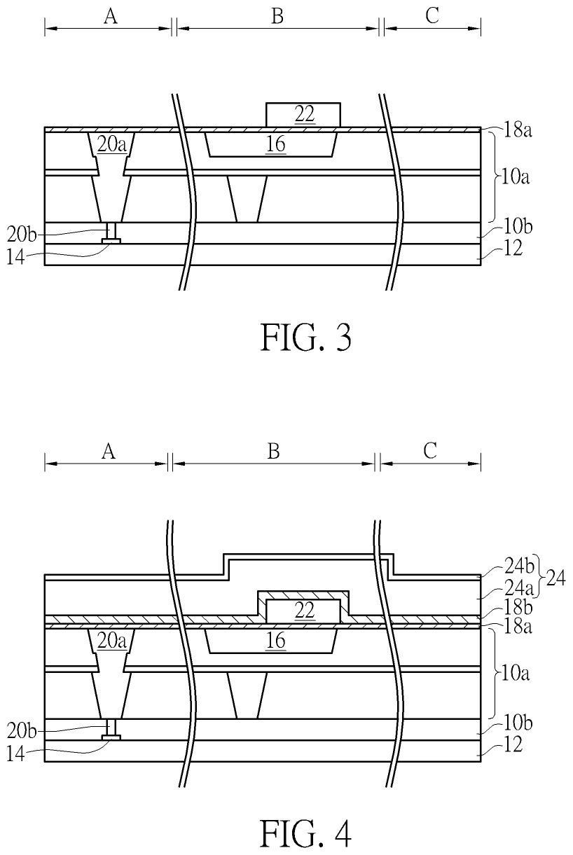

As shown in FIG. 3, the capacitor dielectric layer 22 is patterned to remove the capacitor dielectric layer 22 in the active region A and the heat dispensing region C by using the first heat conductive layer 18a as an etching stop layer. The remaining capacitive dielectric layer 22 remains in the capacitor region B. As shown in FIG. 4, a second heat conductive layer 18b is formed to conformally cover the active region A, the capacitor region B and the heat dispensing region C. The second heat conductive layer 18b contacts the capacitor dielectric layer 22 and the first heat conductive layer 18a. The steps of forming the second heat conductive layer 18b include a physical vapor deposition, a chemical vapor deposition, an atomic layer deposition or other deposition methods. The second heat conductive layer 18b is preferably amorphous aluminum nitride or amorphous boron nitride. Then, a top electrode 24 is formed to conformally cover the second heat conductive layer 18b. The top electrode 24 may be a multi-layered conductive structure, such as a stacked structure of metal layers and metal nitrides. In this embodiment, to give an example, a lower layer 24a of the top electrode 24 is aluminum, and an upper layer 24b of the top electrode 24 is titanium nitride.

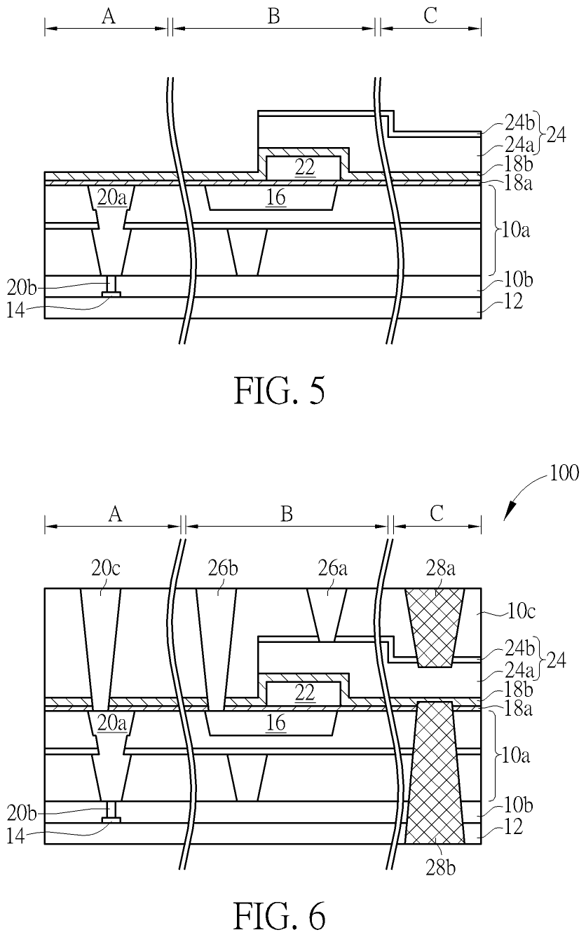

As shown in FIG. 5, the top electrode 24 is patterned to remove the top electrode 24 located in the active region A by using the second heat conductive layer 18b as an etching stop layer. The remaining top electrode 24 is located in the capacitor region B and the heat dispensing region C. At this time, the second heat conductive layer 18b in the active region A is exposed.

As shown in FIG. 6, an inter-metallic dielectric layer 10c is formed to cover the active region A, the capacitor region B and the heat dispensing region C. Then, a metal interconnection structure 20c, a first plug 26a, a second plug 26b and a first heat sink 28a are formed. The metal interconnection structure 20c penetrates the inter-metallic dielectric layer 10c, the second heat conductive layer 18b and the first heat conductive layer 18a within the active region A. The metal interconnection structure 20c contacts the metal interconnection structure 20a, the second heat conductive layer 18b and the first heat conductive layer 18a. The first plug 26a is disposed in the inter-metallic dielectric layer 10c and contacts the top electrode 24. For instance, an end of the first plug 26a contacts the lower layer 24a of the top electrode 24. The second plug 26b penetrates the inter-metallic dielectric layer 10c, the second heat conductive layer 18b and the first heat conductive layer 18a within the capacitor region B to contact the bottom electrode 16. The first heat sink 28a penetrates the inter-metallic dielectric layer 10c in the heat dispensing region C and contacts the top electrode 24. For example, an end of the first heat sink 28a contacts the lower layer 24a of the top electrode 24. The inter-metallic dielectric layer 10c, the first plug 26a, the second plug 26b and the first heat sink 28a are formed by the same fabricating process. For example, several recesses are formed in the inter-metallic dielectric layer 10c for accommodating the metal interconnection structure 20c, the first plug 26a, the second plug 26b and the first heat sink 28a later. Then, a metal layer is formed to fill in the recesses to form the metal interconnection structure 20c, the first plug 26a, the second plug 26b and the first heat sink 28a. After that, a second heat sink 28b is formed in the heat dispensing region C and contacts the first heat conductive layer 18a and the second heat conductive layer 18b. Specifically, the second heat sink 28b is a through silicon via. The second heat sink 28b penetrates the substrate 12, the interlayer dielectric layer 10b, the dielectric layer 10a and the first heat conductive layer 18a. An end of the second heat sink 28b contacts the second heat conductive layer 18b. At this point, a structure 100 of an MIM capacitor and a heat sink of the present invention is completed.

In the foregoing description, although the metal interconnection structure 20c, the first plug 26a, the second plug 26b and the first heat sink 28a are formed earlier than the second heat sink 28b, however, according to different process requirements, the second heat sink 28b can also be fabricated first, and then the metal interconnection structure 20c, the first plug 26a, the second plug 26b and the first heat sink 28a can be fabricated together later.

As shown in FIG. 6, a structure 100 of an MIM capacitor and a heat sink includes a dielectric layer 10a. The dielectric layer 10a includes an active region A, a capacitor region B and a heat dispensing region C. A substrate 12 is disposed below the dielectric layer 10a. The substrate 12 is covered with an interlayer dielectric layer 10b, and the interlayer dielectric layer 10b contacts the dielectric layer 10a. The substrate 12, the interlayer dielectric layer 10b and the dielectric layer 10a are all divided into the active region A, the capacitor region B and the heat dissipating region C. A power amplifier 14 is disposed on the substrate 12 within the active region A. A metal interconnection structure 20b is disposed in the interlayer dielectric layer 10b to electrically connect the power amplifier 14. A metal interconnection structure 20a is disposed within the dielectric layer 10a to contact the metal interconnect structure 20b. A bottom electrode 16 is embedded in the dielectric layer 10a within the capacitor region B. A first heat conductive layer 18a covers the dielectric layer 10a within the active region A, the capacitor region B and the heat dissipating region C. The first heat conductive layer 18a contacts the bottom electrode 16 and the metal interconnection structure 20b. A capacitor dielectric layer 22 is only disposed on the first heat conductive layer 18a within the capacitor region B. The capacitor dielectric layer 22 contacts the first heat conductive layer 18a. A second heat conductive layer 18b contacts the capacitor dielectric layer 22 and the first heat conductive layer 18a. The second heat conductive layer 18b is disposed within the active region A, the capacitor region B and the heat dispensing region C. A top electrode 24 is disposed on the capacitor region B and the heat dispensing region C, and covers and contacts the second heat conductive layer 18b.

An inter-metallic dielectric layer 10c covers the active region A, the capacitor region B and the heat dispensing region C. In details, the inter-metallic dielectric layer 10c is disposed above the top electrode 24 and the second heat conductive layer 18b. A metal interconnection structure 20c penetrates the inter-metallic dielectric layer 10c, the second heat conductive layer 18b and the first heat conductive layer 18a within the active region A. The metal interconnection structure 20c contacts the metal interconnection structure 20a, the second heat conductive layer 18b and the first heat conductive layer 18a.

A first heat sink 28a is disposed in the inter-metallic dielectric layer 10c in heat dispensing region C and contacts the top electrode 24. A second heat sink 28b is disposed in the heat dispensing area C and contacts the first heat conductive layer 18a and the second heat conductive layer 18b. The second heat sink 28b is a through silicon via. The second heat sink 28b penetrates the substrate 12, the interlayer dielectric layer 10b, the dielectric layer 10a and the first heat conductive layer 18a. An end of the second heat sink 28b contacts the second heat conductive layer 18b.

A first plug 26a is disposed in the inter-metallic dielectric layer 10c within the capacitor region B and contacts the top electrode 24. A second plug 26b is located on the inter-metallic dielectric layer 10c in the capacitor region B and contacts the bottom electrode 16. In details, the top electrode 24 preferably includes a multi-layered conductive structure. In this embodiment, a lower layer 24a of the top electrode 24 is aluminum, and an upper layer 24b of the top electrode 24 is titanium nitride. The thickness of the lower layer 24a is greater than that of the upper layer 24b. In this way, the resistance of the top electrode 24 can be reduced, and the charge/discharge speed of the MIM capacitor can be accelerated.

Furthermore, according to a preferred embodiment of the present invention, an end of the first plug 26a contacts the lower layer 24a of the top electrode 24, and an end of the second plug 26b contacts a surface of the bottom electrode 16.

The bottom electrode 16 and the top electrode 24 may respectively include TIN, Al, Ta, Cu, Ti, or Ta. The capacitor dielectric layer 22 is typically fabricated from a layer or layers of materials having a high dielectric constant (high K) such as HfO₂, Al₂O₃, ZrO₂, barium strontium titanate (BST), lead zirconate titanate (PZT), ZrSiO₄, HfSiO₂, HfSiON, TaO₂, or a combinations thereof.

The first heat conductive layer 18a and the second heat conductive layer 18b include amorphous aluminum nitride or amorphous boron nitride. Since the materials used for the first heat conductive layer 18a and the second heat conductive layer 18b are insulating materials with high thermal conductivity. Especially amorphous aluminum nitride or amorphous boron nitride has a high energy band gap, therefore, current leakage of the capacitor dielectric layer 22 can be prevented. In addition, it should be noted that: the first heat conductive layer 18a and the second heat conductive layer 18b contact the top surface and the bottom surface of the capacitor dielectric layer 22 respectively. The first heat conductive layer 18a and the second heat conductive layer 18b also contact the second heat sink 28b and the top electrode 24. Moreover, the first heat conductive layer 18a and the second heat conductive layer 18b specially extend to the active region A to contact the metal interconnection structure 20a. In this way, the heat generated by the power amplifier 14 can be transferred to the second heat sink 28b and the top electrode 24 through the first heat conductive layer 18a and the second heat conductive layer 18b. Furthermore, because the first heat conductive layer 18a and the second heat conductive layer 18b contact the capacitor dielectric layer 22 respectively, the heat generated by the capacitor dielectric layer 22 can also be transferred to the second heat sink 28b and the top electrode 24 through the first heat conductive layer 18a and the second heat conductive layer 18b. Because the top electrode 24 contacts the first heat sink 28a, heat can be sent from the top electrode 24 to outside through the first heat sink 28a and the heat transferred to the second heat sink 28b is sent to the outside by the second heat sink 28b itself.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A structure of a metal-insulator-metal (MIM) capacitor and a heat sink, comprising:
a dielectric layer, wherein the dielectric layer comprises a capacitor region and a heat dispensing region;
a bottom electrode embedded in the dielectric layer;
a first heat conductive layer covering the dielectric layer and the heat dispensing region;
a capacitor dielectric layer disposed on the first heat conductive layer within the capacitor region;
a second heat conductive layer covering and contacting the capacitor dielectric layer and the first heat conductive layer, wherein the second heat conductive layer is disposed within the capacitor region and the heat dispensing region;
a top electrode disposed within the capacitor region and the heat dispensing region, and covering the second heat conductive layer;
a first heat sink disposed within the heat dispensing region and contacting the top electrode; and
a second heat sink disposed within the heat dispensing region and contacting the first heat conductive layer and the second heat conductive layer.

2. The structure of an MIM capacitor and a heat sink of claim 1, wherein the second heat sink penetrates the dielectric layer and an end of the second heat sink contacts the first heat conductive layer and the second heat conductive layer.

3. The structure of an MIM capacitor and a heat sink of claim 1, wherein the capacitor dielectric layer is only disposed in the capacitor region.

4. The structure of an MIM capacitor and a heat sink of claim 1, wherein an end of the first heat sink contacts the top electrode.

5. The structure of an MIM capacitor and a heat sink of claim 1, further comprising a first plug disposed in the capacitor region and contacting the top electrode, and a second plug disposed in the capacitor region and contacting the bottom electrode.

6. The structure of an MIM capacitor and a heat sink of claim 1, wherein the dielectric layer further comprising:
an active region; and
a metal interconnection structure disposed within the dielectric layer within the active region, wherein the first heat conductive layer and the second heat conductive layer extend to the active region, and the second heat conductive layer contacts the metal interconnection structure.

7. The structure of an MIM capacitor and a heat sink of claim 6, further comprising:
a substrate disposed under the dielectric layer; and
a power amplifier disposed on the substrate, wherein the power amplifier is electrically connected to the metal interconnection structure.

8. The structure of an MIM capacitor and a heat sink of claim 7, wherein the second heat sink is a through silicon via, and the second heat sink penetrates the substrate.

9. The structure of an MIM capacitor and a heat sink of claim 1, wherein the first heat conductive layer comprises amorphous aluminum nitride, and the second heat conductive layer comprises amorphous aluminum nitride.

10. A fabricating method of a structure of a metal-insulator-metal (MIM) capacitor and a heat sink, comprising:
providing a dielectric layer, wherein the dielectric layer comprises a capacitor region and a heat dispensing region;
forming a bottom electrode embedded in the dielectric layer;
forming a first heat conductive layer covering the capacitor region and the heat dispensing region of the dielectric layer;
forming a capacitor dielectric layer disposed on the first heat conductive layer within the capacitor region;
forming a second heat conductive layer covering and contacting the capacitor dielectric layer and the first heat conductive layer, wherein the second heat conductive layer is disposed within the capacitor region and the heat dispensing region;
forming a top electrode disposed within the capacitor region and the heat dispensing region, wherein the top electrode covers the second heat conductive layer;
forming a first heat sink disposed on the heat dispensing region and contacting the top electrode; and
forming a second heat sink disposed within the heat dispensing region, contacting the first heat conductive layer and the second heat conductive layer.

11. The fabricating method of a structure of an MIM capacitor and a heat sink of claim 10, wherein the second heat sink penetrates the dielectric layer and an end of the second heat sink contacts the first heat conductive layer and the second heat conductive layer.

12. The fabricating method of a structure of an MIM capacitor and a heat sink of claim 10, wherein the capacitor dielectric layer is only disposed in the capacitor region.

13. The fabricating method of a structure of an MIM capacitor and a heat sink of claim 10, wherein an end of the first heat sink contacts the top electrode.

14. The fabricating method of a structure of an MIM capacitor and a heat sink of claim 10, further comprising:
forming a first plug disposed in the capacitor region and contacting the top electrode; and
forming a second plug disposed in the capacitor region and contacting the bottom electrode.

15. The fabricating method of a structure of an MIM capacitor and a heat sink of claim 10, wherein the dielectric layer further comprising:
an active region, wherein a metal interconnection structure disposed within and on the dielectric layer within the active region, the first heat conductive layer and the second heat conductive layer extend to the active region, and the second heat conductive layer contacts the metal interconnection structure.

16. The fabricating method of a structure of an MIM capacitor and a heat sink of claim 15, further comprising:
a substrate disposed under the dielectric layer; and
a power amplifier disposed on the substrate, wherein the power amplifier is electrically connected to the metal interconnection structure.

17. The fabricating method of a structure of an MIM capacitor and a heat sink of claim 16, wherein the second heat sink is a through silicon via, and the second heat sink penetrates the substrate.

18. The fabricating method of a structure of an MIM capacitor and a heat sink of claim 16, wherein the first heat conductive layer comprises amorphous aluminum nitride, and the second heat conductive layer comprises amorphous aluminum nitride.
